(19) United States
(12) Patent Application Publication
(10) Pub. No.: US 2012/0313262 A1
(43) Pub. Date: Dec. 13, 2012

(54) STACKED SEMICONDUCTOR DEVICE

(75) Inventor: Takehiro Suzuki, Yokohama-shi (JP)

(73) Assignee: CANON KABUSHIKI KAISHA, Tokyo (JP)

(21) Appl. No.: 13/579,109

(22) PCT Filed: Feb. 10, 2011
(86) PCT No.: PCT/JP2011/000745

§ 371 Date: Aug. 15, 2012

(30) Foreign Application Priority Data
Feb. 17, 2010 (JP) 2010-032320

(51) Int. Cl. H01L 25/00

(52) U.S. Cl. 257/777; 257/E25.001

(57) ABSTRACT

A stacked semiconductor device includes a plurality of first electrodes provided on a first printed wiring board and columnar electrodes provided on the first electrodes. The stacked semiconductor device also includes a plurality of second electrodes provided on a second printed wiring board and a plurality of solder electrodes. The columnar electrodes are formed of a material having a melting point higher than that of the solder electrodes, and the height of the columnar electrodes is set to increase as a distance between the first electrodes and the solder electrodes increases. This avoids connection failure without reducing joinability between two stacked semiconductor devices.

### TECHNICAL FIELD

The present invention relates to a stacked semiconductor device in which two or more semiconductor devices each including a semiconductor element are stacked and mounted in a three-dimensional manner.

### BACKGROUND ART

The size and weight of digital apparatuses, including digital cameras and digital video cameras, have been reduced. To mount components in a smaller space, a semi-conductor device capable of higher-density mounting has been used. Moreover, three-dimensional mounting that can further save the mounting space has attracted attention. As the semiconductor device, semiconductor packages, such as a chip size package (CSP) and a ball grid array (BGA) package, are often adopted. The term “CSP” is a general name of packages having sizes equivalent to or slightly larger than the chip size, and the term “BGA package” refers to a semiconductor package in which solder balls are used as electrodes. Three-dimensional mounting is roughly classified into the following two methods. In one method, two or three semiconductor elements are stacked in a semiconductor package such as a CSP or a BGA package. In the other method, a plurality of semiconductor packages are stacked to form a stacked semi-conductor device. In a stacked semiconductor device, one semiconductor package has a semiconductor element connected to a printed wiring board, and another semi-conductor package is connected thereon. To connect the semiconductor packages, solder paste or the like is transferred onto electrodes on the printed wiring board in the upper semiconductor package, the upper semiconductor package is aligned with electrodes on a printed wiring board of the lower semiconductor package, and the semiconductor packages are then connected by heating in a reflow process. However, since these semiconductor packages are formed of different materials, they are warped by heating. This warping causes connection failure with a motherboard or connection failure between the semiconductor packages.

Accordingly, PTL 1 discloses a method for avoiding connection failure resulting from warping of a printed wiring board in a semiconductor package. In PTL 1, the volumes of solder bumps are different according to the warping shape of the printed wiring board. Further, in PTL 2, conductive paste is printed on lands of a printed wiring board in one semiconductor package, and another semiconductor package having solder balls is mounted thereon. Then, the conductive paste and the solder balls are melted by a reflow process, thereby connecting the electrodes on a pair of upper and lower printed wiring boards.

In the semiconductor device of PTL 1 in which the volumes of the solder bumps are different, since the amount of solder necessary for joint cannot be reduced, it is necessary to increase the amount of solder at the solder bumps corresponding to greatly warped portions of the printed wiring board. However, if the amount of solder at the solder bumps increases, a bridge is likely to be formed between the solder bumps by heating. This increases the risk of connection failure.

In the semiconductor device of PTL 2 in which the conductive paste is printed, the solder balls and the conductive paste are melted and mixed by heating, thereby forming bumps. However, since the solder balls and the conductive paste are melted by heating, the volume of melted metal for forming the bumps increases, and connection failure occurs, for example, a bridge is formed between adjacent electrodes. Particularly in a greatly warped portion of the printed wiring board, it is necessary to increase the amount of conductive paste, and the amount of metal to be melted increases. As a result, a bridge is easily formed, and the risk of connection failure increases.

### CITATION LIST

### Patent Literature

PTL 1: Japanese Patent Laid-Open No. 2001-85558
PTL 2: U.S. Pat. No. 7,091,619

### SUMMARY OF INVENTION

The present invention provides a stacked semiconductor device that can avoid connection failure without reducing joinability between two stacked semiconductor devices.

A stacked semiconductor device according to an aspect of the present invention includes: a first semiconductor device comprising a first printed wiring board, a first semiconductor element mounted on the first printed wiring board, a plurality of first electrodes provided on one surface of the first printed wiring board, and a plurality of external electrodes provided on the other surface of the first printed wiring board; and a second semiconductor device stacked on the first semiconductor device and comprising a second printed wiring board, a second semiconductor element mounted on the second printed wiring board, a plurality of second electrodes provided on one surface of the second printed wiring board facing the first printed wiring board, and solder electrodes provided on the second electrodes. The first electrodes and the solder electrodes are connected by columnar electrodes, and a height of the columnar electrodes is set to increase as a distance between the first electrodes and the solder electrodes increases.

Further features of the present invention will become apparent from the following description of exemplary embodiments with reference to the attached drawings.

### BRIEF DESCRIPTION OF DRAWINGS

FIGS. 1A and 1B are cross-sectional views schematically illustrating a con-figuration of a stacked semiconductor device according to a first embodiment of the present invention, FIG. 1A illustrates a state of the stacked semiconductor device after heating, and FIG. 1B illustrates a state of the stacked semiconductor device before heating.

FIG. 2 is a cross-sectional view illustrating the warp amounts of printed wiring boards provided when the semiconductor devices are heated.

FIG. 3 is a partially enlarged cross-sectional view of a columnar electrode and its surroundings in a first semiconductor device.

FIG. 4 is a cross-sectional view schematically illustrating a configuration of a stacked semiconductor device according to a second embodiment of the present invention.

FIG. 5 is a cross-sectional view schematically illustrating a configuration of a stacked semiconductor device according to a further embodiment of the present invention.

FIG. 6 is a cross-sectional view schematically illustrating a configuration of a stacked semiconductor device according to a still further embodiment of the present invention.

### DESCRIPTION OF EMBODIMENTS

Embodiments of the present invention will be described in detail below with reference to the drawings.

### First Embodiment

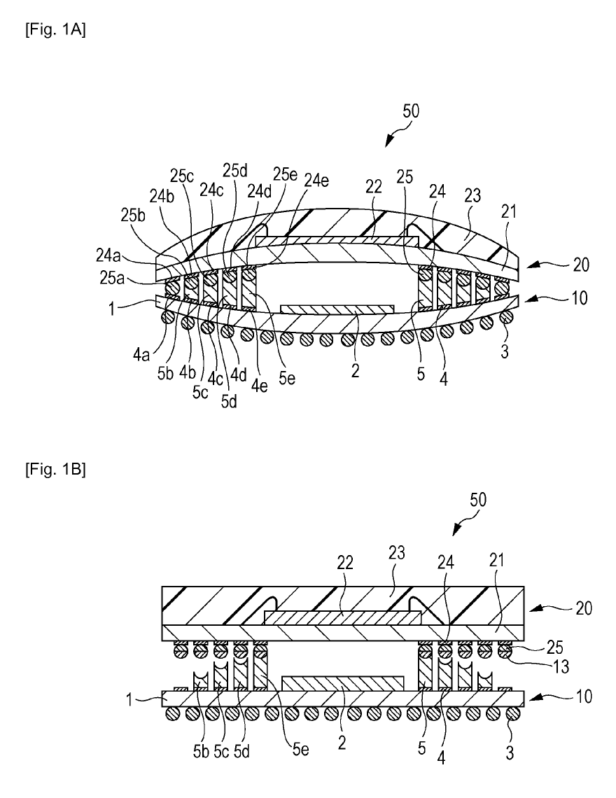

FIGS. 1A and 1B schematically illustrate a configuration of a stacked semiconductor device 50 according to a first embodiment of the present invention. FIG. 1A illustrates a state of the stacked semiconductor device 50 after heating, and FIG. 1B illustrates a state of the stacked semiconductor device 50 before heating. Referring to FIG. 1A, the stacked semiconductor device 50 includes a first semiconductor device 10 and a second semiconductor device 20 stacked on the first semiconductor device 10.

The first semiconductor device 10 is a semiconductor package comprising a first printed wiring board 1 serving as an interposer and a first semiconductor element 2 mounted on the first printed wiring board 1. When a surface of the first printed wiring board 1 on which the first semiconductor element 2 is mounted is a front surface and an opposite surface is a back surface, a plurality of solder balls 3 serving as external electrodes are provided on the back surface so as to be connectable to a motherboard or the like (not illustrated). In contrast, on the front surface of the first printed wiring board 1, a plurality of first electrodes 4 (4a, 4b, 4c, 4d, and 4e) are arranged in a lattice form so as to surround the first semiconductor element 2. The first electrodes 4 are electrode pads shaped like flat plates having the same area. More specifically, the electrodes 4 are shaped like circular plate having the same diameter. The first electrodes 4a are provided on the outermost periphery of the first printed wiring board 1. On the inner sides of the first electrodes 4a, the other first electrodes 4b, 4c, 4d, and 4e are arranged in order toward the center on the first printed wiring board 1. Here, the term “the same” includes “approximately the same” within the tolerance. This also applies to the following description.

The second semiconductor device 20 is a semiconductor package comprising a second printed wiring board 21 serving as an interposer, a second semiconductor element 22 mounted on the second printed wiring board 21, and mold resin 23 covering the second semiconductor element 22. The second printed wiring board 21 and the second semiconductor element 22 are joined together by wire bonding.

When a surface of the second printed wiring board 21 on which the second semi-conductor element 22 is mounted is a front surface and an opposite surface is a back surface, a plurality of second electrodes 24 (24a, 24b, 24c, 24d, and 24e) opposing the first electrodes 4 of the first semiconductor device 10 are provided on the back surface. The second electrodes 24 are electrode pads shaped like flat plates having the same area. More specifically, the second electrodes 24 are shaped like circular plates having the same diameter. The second electrodes 24a are provided on the outer periphery of the second printed wiring board 21. On the inner sides of the second electrodes 24a, the other second electrodes 24b, 24c, 24d, and 24e are arranged in order toward the center on the second printed wiring board 21.

The second electrodes 24 are provided with solder electrodes 25 (25a, 25b, 25c, 25d, and 25e), respectively. The solder electrodes 25 are ball-shaped, and the amounts of solder thereof are set to be equal. For example, the length of one side of each of the printed wiring boards 1 and 21 is 12 to 14 mm, and the length of one side of the first semiconductor element 2 is 6 to 8 mm.

Before being heated for solder joint, the printed wiring boards 1 and 21 are not warped, as illustrated in FIG. 1B. However, when the printed wiring boards 1 and 21 are heated for solder joint, they are warped, as illustrated in FIG. 1A. In the first embodiment, at a temperature of 220 degrees where solder melts, the first printed wiring board 1 thermally deforms in a downward convex shape (upward concave shape) and the second printed wiring board 21 thermally deforms in an upward convex shape (downward concave shape). That is, the first and second printed wiring boards 1 and 21 are deformed by heating so that the distance between the first electrodes 4 and the second electrodes 24 increases from the outer peripheries of the first and second printed wiring boards 1 and 21 toward the center portion. Here, the warp amounts of the first printed wiring board 1 and the second printed wiring board 21 are obtained beforehand by experiment or other methods.

In the first embodiment, the first semiconductor device 10 includes columnar electrodes 5 (5b, 5c, 5d, and 5e) provided on the first electrodes 4 (4b, 4c, 4d, and 4e). The columnar electrodes 5 are formed of a high-melting-point material that melts at a melting point higher than that of the solder electrodes 25 (e.g., Cu (melting point: 1083 degrees). The thickness (diameter) of the columnar electrodes 5 is set to be equal to that of the first electrodes 4. The height of the columnar electrodes 5 is set so that ends of the solder electrodes 25 and ends of the columnar electrodes 5 come into contact with each other when the printed wiring boards 1 and 21 thermally deform. That is, the height of the columnar electrodes 5 is set to increase as the distance between the first electrodes 4 and the solder electrodes 25 increases. Herein, the term “the height of the columnar electrodes 5” refers to the projection amount of the columnar electrodes 5 toward the solder electrodes 25 (toward the second electrodes 24). Before the first printed wiring board 1 thermally deforms, the columnar electrodes 5 are perpendicular to the first printed wiring board 1, as illustrated in FIG. 1B. The height of the columnar electrodes 5 is set to increase from the outer periphery of the first printed wiring board 1 toward the center portion.

In the first embodiment, the second electrodes 24a provided on the outer periphery of the second printed wiring board 21 are directly connected to the first electrodes 4a of the first printed wiring board 1 by the solder electrodes 25a. Further, the second electrodes 24b, 24c, 24d, and 24e located on the inner sides of the second electrodes 24a are connected to the first electrodes 4b, 4c, 4d, and 4e by the solder electrodes 25b, 25c, 25d, and 25e via the columnar electrodes 5b, 5c, 5d, and 5e. That is, the columnar electrodes 5b to 5e are provided on the first electrodes 4b to 4e other than the first electrodes 4a corresponding to positions where the distance is the minimum. While columnar electrodes are not provided on the first electrodes 4a in the first embodiment, they may be provided on the first electrodes 4a.

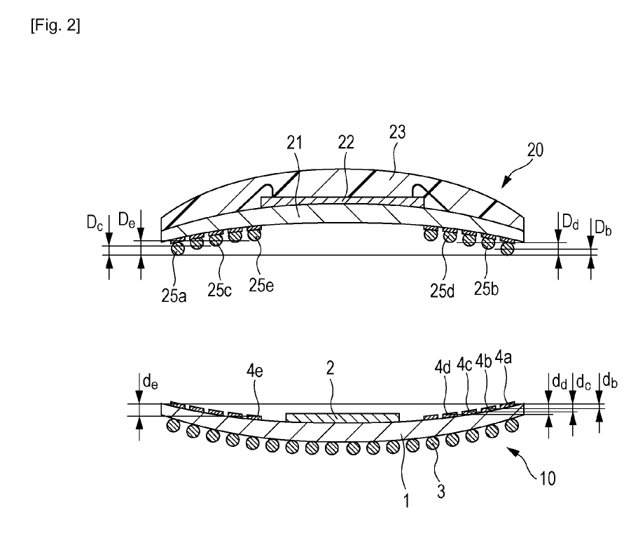

A method for setting the height of the columnar electrodes 5 will be specifically described below. FIG. 2 illustrates the warp amounts of the printed wiring boards provided when the semiconductor devices 10 and 20 are heated. First, the first semi-conductor device 10 and the second semiconductor device 20 are heated, and the warp amounts thereof at different temperatures are measured (measurement apparatus: core9030b from Cores Corporation). As illustrated in FIG. 2, near the temperature of 220 degrees, the first printed wiring board 1 of the first semiconductor device 10 warps in a downward convex shape, and the second printed wiring board 21 of the second semiconductor device 20 warps in an upward convex shape.

In this state, the differences in height of the ends of the first electrodes 4b, 4c, 4d, and 4e from the ends of the first electrodes 4a on the outer periphery of the first printed wiring board 1 of the first semiconductor device 10 are measured. These differences in height are designated as d_{b}, d_{c}, d_{d}, and dₑ, respectively. Similarly, the differences in height of the ends of the solder electrodes 25b, 25c, 25d, and 25e from the ends of the solder electrodes 25a on the outer periphery of the second printed wiring board 21 of the second semiconductor device 20 are measured. These differences in height are designated as D_{b}, D_{c}, D_{d}, and Dₑ, respectively. The sums of the differences in height calculated from the warp amounts of the printed wiring boards 1 and 21, that is, d_{b}+D_{b}, d_{c}+D_{c}, d_{d}+D_{d}, and dₑ+Dₑ are distances between the first electrodes 4b to 4e and the solder electrodes 25b to 25e. Therefore, in the first embodiment, the heights of the columnar electrodes 5b to 5e are set to be equal to the calculated distances. For example, the heights d_{b}+D_{b}, d_{c}+D_{c}, d_{d}+D_{d}, and dₑ+Dₑ of the columnar electrodes 5b, 5c, 5d, and 5e are about 20 micrometers, about 30 micrometer, about 40 micrometers, and about 50 micrometers, respectively. Thus, the height gradually changes according to the calculated distance. These values are set in consideration of the sizes of the printed wiring boards 1 and 21 and the size of the first semiconductor element 2. The columnar electrodes 5 are stacked on the first electrodes 4 by multistep plating or other methods.

Next, a production procedure for the stacked semiconductor device 50 will be described. First, as illustrated in FIG. 1B, solder paste 13 is transferred onto solder electrodes 25 on a second semiconductor device 20, and the second semiconductor device 20 is placed on a first semiconductor device 10. In this case, since columnar electrodes 5 formed of a high-melting-point material are provided, the solder electrodes 25 (25e) of the second semiconductor device 20 contact only the columnar electrodes 5e on the innermost periphery of the first semiconductor device 10.

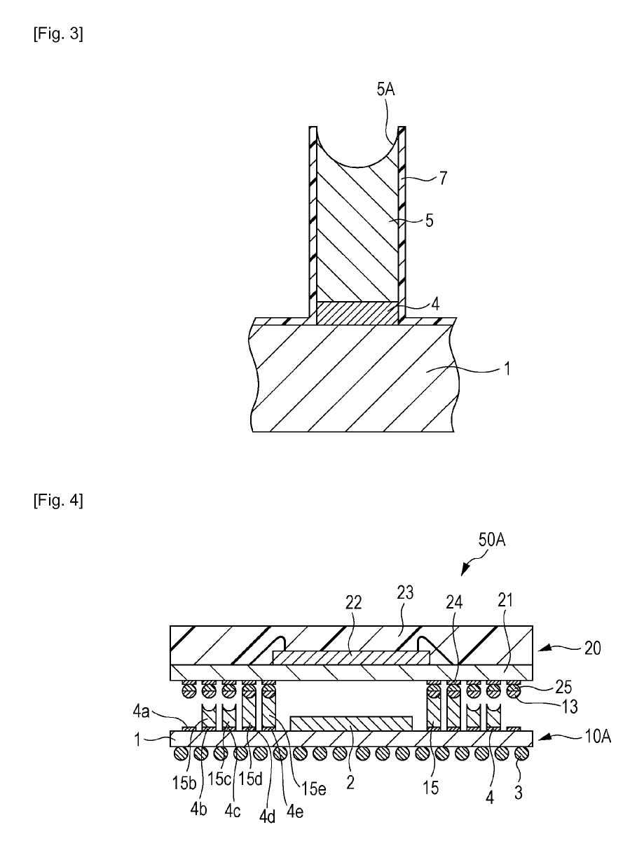

As illustrated in FIG. 3, a tip 5A of each columnar electrode 5 is concave such as to receive the corresponding solder electrode 25. The tip 5A of the columnar electrode 5 is concave to have a radius of curvature equivalent to or equal to that of an arc of the solder electrode 25, and is worked so that the solder electrode 25 is fitted therein. This allows the second semiconductor device 20 to be stably positioned on the first semi-conductor device 10, and prevents mounting displacement, for example, prevents the solder electrode 25 from slipping off the columnar electrode 5 before solder joint. Moreover, even when the solder electrode 25 is melted by heating, the melted solder can be restrained from flowing down from the tip 5A of the columnar electrode 5.

Next, in a reflow process, heating is performed at a temperature of 220 degrees (a melting point of solder (Sn₃Ag_{0.5}Cu)) or more (about 250 degrees). Then, the first semiconductor device 10 and the second semiconductor device 20 thermally deform, all of the solder electrodes 25a to 25e are melted and joined into contact with the second electrodes 4a and the columnar electrodes 5b to 5e.

To prevent each solder electrode 25 from spreading to the bottom of the corresponding columnar electrode 5a, a side surface of the columnar electrode 5 is coated with a coating material 7 having a solder wettability lower than that of the material of the columnar electrode 5, such as a solder resist, as illustrated in FIG. 3. This coating material 7 can effectively restrain the melted solder from flowing down from the tip 5A of the columnar electrode 5. Further, when the coating material 7 is formed of the same material as a solder resist provided on the first printed wiring board 1, a step of forming the coating material 7 can be performed in a resist forming process. This shortens the production time.

As described above, in the first embodiment, the height of the columnar electrodes 5 is set to increase as the distance between the first electrodes 4 and the solder electrodes 25 is increased by warping of the first printed wiring board 1 and the second printed wiring board 21. Therefore, even when the amounts of solder at the solder electrodes 25 are equal, the printed wiring boards 1 and 21 can be properly joined without reducing joinability. Further, since the amounts of solder at the solder electrodes 25 are equal, a bridge is rarely formed between the adjacent solder electrodes. This avoids connection failure.

### Second Embodiment

Next, a stacked semiconductor device 50A according to a second embodiment of the present invention will be described with reference to FIG. 4. FIG. 4 is a schematic cross-sectional view illustrating a configuration of the stacked semiconductor device 50A of the second embodiment in a state immediately after a second semiconductor device 20 is placed on a first semiconductor device 10A (at room temperature). In FIG. 4, components similar to those adopted in the above first embodiment are denoted by the same reference numerals. The amounts and directions of warping of first and second printed wiring boards 1 and 21 are similar to those of the first embodiment.

In the second embodiment, the stacked semiconductor device 50A includes the first semiconductor device 10A and the second semiconductor device 20 stacked on the first semiconductor device 10A. The first semiconductor device 10A includes columnar electrodes 15 (15b, 15c, 15d, and 15e) provided on first electrodes 4b to 4e of the first printed wiring board 1.

The columnar electrodes 15 are formed of a high-melting-point material that melts at a melting point higher than that of solder electrodes 25 (e.g., Cu (melting point: 1083 degrees). The height of each columnar electrode 15 is set so that an end of the corresponding solder electrodes 25 and an end of the columnar electrode 15 come into contact with each other when the printed wiring boards 1 and 21 are thermally deformed. That is, the height of the columnar electrodes 15 is set to increase as the distance between the first electrodes 4 and the second electrodes 24 increases.

The warp amounts of the printed wiring boards 1 and 21 at positions of the adjacent columnar electrodes 15 (that is, distances) are not greatly different. Even if the heights of at least two adjacent columnar electrodes 15 are equally set, solder joint failure does not occur. For example, when the distances between the first electrodes 4b, 4c, 4d, and 4e and the solder electrodes 25b, 25c, 25d, and 25e are about 20 micrometers, about 30 micrometers, about 40 micrometers, and about 50 micrometers, respectively, the differences between the adjacent distances is about 10 micrometers, and this does not cause solder joint failure.

Accordingly, in the second embodiment, the projection amount of the columnar electrodes 15 is set to increase stepwise from the outer periphery of the first printed wiring board 1 toward the center portion. That is, in the second embodiment, the height of the columnar electrodes 15d adjacent to the tallest columnar electrodes 15e corresponding to positions where the distance between the first electrodes 4 and the solder electrodes 24 is the longest, of a plurality of columnar electrodes 15b to 15e, is set to be equal to the height of the tallest columnar electrodes 15e. For example, the heights of the columnar electrodes 15d and 15e are equally set at about 50 micrometers. Further, the heights of the columnar electrodes 15b and 15c are equally set at, for example, about 20 micrometers.

Thus, when being placed on the first semiconductor device 10A before heating, the second semiconductor device 20 is supported by the columnar electrodes 15e on the innermost periphery and the adjacent columnar electrodes 15d. When the first printed wiring board 1 warps in an upward convex shape and the second printed wiring board 21 warps in a downward convex shape, the distance between the first electrodes and the solder electrodes on the outermost peripheries of the printed wiring boards becomes the longest. In this case, the height of the columnar electrodes on the outermost periphery is set to be equal to the height of the columnar electrodes on the second outermost periphery.

The above-described second embodiment provides the following advantages in addition to the advantages similar to those of the first embodiment. That is, since the number of columnar electrodes 15 that support the second semiconductor device 20 before heating is larger than in the first embodiment, the second semiconductor device 20 is supported more stably. Therefore, it is possible to effectively prevent displacement of the second semiconductor device 20.

While the present invention has been described in conjunction with the embodiments, the invention is not limited thereto. While a single package in which one semi-conductor element is mounted on each printed wiring board is adopted in the above embodiments, a stacked package in which a plurality of semiconductor elements are mounted may be adopted.

While the stacked semiconductor devices 50 and 50A of the above embodiments each include two semiconductor devices, they may include three or more semi-conductor devices. In this case, two adjacent semiconductor devices of the three or more semiconductor devices correspond to the first and second semiconductor devices.

While the first printed wiring board 1 warps in a downward convex shape and the second printed wiring board 21 warps in an upward convex shape in the above embodiments, the printed wiring boards may exhibit different warping behavior according to the structure and physical property of the semiconductor device. The present invention is applicable to any warping shape.

While the columnar electrodes 5 and 15 are stacked by multistep plating in the above embodiments, they may be formed of Au or Cu using a stud bump bonder or the like. When columnar electrodes (stud bumps) are formed using the stud bump bonder or the like, ends of the columnar electrodes are made concave using a jig having a hemispherical end.

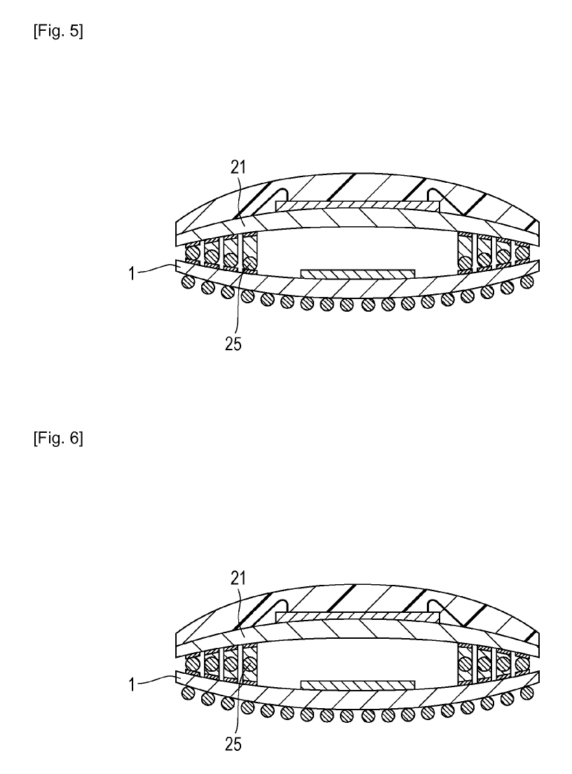

In the above embodiments, the columnar electrodes are provided on the first printed wiring board 1 and the solder electrodes 25 are provided on the second printed wiring board 21. However, the present invention is not limited thereto. As illustrated in FIG. 5, the columnar electrodes may be provided on the second printed wiring board 21 and the solder electrodes 25 may be provided on the first printed wiring board 1.

Alternatively, as illustrated in FIG. 6, columnar electrodes may be provided on both the first printed wiring board 1 and the second printed wiring board 21, and solder electrodes 25 may be provided therebetween. In this case, the sum of the heights of the columnar electrodes on the first printed wiring board 1 and the heights of the columnar electrodes on the first printed wiring board 1 is set in correspondence with the distances between the first electrodes and the solder electrodes.

While the second semiconductor element 22 is mainly connected to the second printed wiring board 21 by wire bonding and is covered with the mold resin 23 in the above embodiments, the second semiconductor element 22 does not always need to be covered with mold resin, as in a wafer level package (WLP). Further, the second semiconductor element 22 and the second printed wiring board 21 may be connected by flip chip bonding instead of wire bonding. When the second semiconductor element 22 and the second printed wiring board 21 are connected by flip chip bonding, a wiring surface of the semiconductor element is coated with resin.

According to the present invention, the height of the columnar electrodes increases as the distance between the first electrodes and the second electrodes increases. Therefore, even when the amounts of solder at the solder electrodes are equal, the printed wiring boards can be joined without reducing joinability. Moreover, since the amounts of solder at the solder electrodes are equal, a bridge is rarely formed between adjacent solder electrodes. This avoids connection failure.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-032320, filed Feb. 17, 2010, which is hereby incorporated by reference herein in its entirety.

1. A stacked semiconductor device comprising:
a first semiconductor device comprising a first printed wiring board, a first semiconductor element mounted on the first printed wiring board, a plurality of first electrodes provided on one surface of the first printed wiring board, and a plurality of external electrodes provided on the other surface of the first printed wiring board; and
a second semiconductor device stacked on the first semiconductor device and comprising a second printed wiring board, a second semi-conductor element mounted on the second printed wiring board, a plurality of second electrodes provided on one surface of the second printed wiring board facing the first printed wiring board, and solder electrodes provided on the second electrodes,
wherein the first electrodes and the solder electrodes are connected by columnar electrodes, and a height of the columnar electrodes is set to increase as a distance between the first electrodes and the solder electrodes increases.

2. The stacked semiconductor device according to claim 1, wherein the columnar electrodes are formed of a material having a melting point higher than a melting point of the solder electrodes.

3. The stacked semiconductor device according to claim 1, wherein the height of the columnar electrodes gradually increases or decreases from center portions toward outer peripheral portions of the first and second printed wiring boards.

4. The stacked semiconductor device according to claim 1, wherein tips of the columnar electrodes are concave such as to receive the solder electrodes.

5. The stacked semiconductor device according to claim 1, wherein the height of the columnar electrode adjacent to the tallest columnar electrode corresponding to a position where the distance is the longest, of the columnar electrodes, is set to be equal to the height of the tallest columnar electrode.

6. The stacked semiconductor device according to claim 5, wherein side surfaces of the columnar electrodes are each provided a coating material having a solder wettability lower than a solder wettability of the columnar electrodes.
